(19) United States
(12) Patent Application Publication
(10) Pub. No.: US 2024/0206068 A1
(43) Pub. Date: Jun. 20, 2024

(54) PRINTED CIRCUIT BOARD

(71) Applicant: SAMSUNG ELECTRONICS CO., LTD., Suwon-si (KR)

(72) Inventors: Yang LIU, Suzhou Industrial Park (CN); Zhenrong YANG, Suzhou Industrial Park (CN)

(73) Assignee: SAMSUNG ELECTRONICS CO., LTD., Suwon-si (KR)

(21) Appl. No.: 18/384,709

(22) Filed: Oct. 27, 2023

(30) Foreign Application Priority Data
Dec. 14, 2022 (CN) 202211611634.1

(51) Int. Cl. H05K 1/14; H05K 1/02; H05K 1/03; H05K 3/28

(52) U.S. Cl. CPC H05K 1/142; H05K 1/0271; H05K 1/0373; H05K 3/28; H05K 2201/099; H05K 2203/1173

(57) ABSTRACT

A printed circuit board, divided into a printed circuit board area and a peripheral area surrounding the printed circuit board area, includes: a plurality of unit printed circuit boards provided in the printed circuit board area; a base portion provided in the peripheral area and the printed circuit board area, and including a circuit pattern portion and an insulating material portion; a first solder resist portion provided in the peripheral area on a first surface of the base portion and a second surface of the base portion, the first surface being opposite to the second surface; and a second solder resist portion provided in the printed circuit board area on the first surface of the base portion and the second surface of the base portion. The first solder resist portion surrounds the second solder resist portion in the printed circuit board area. The first solder resist portion includes a first filler and the second solder resist portion includes a second filler that is different from the first filler.

### CROSS-REFERENCE TO RELATED APPLICATION

This application is based on and claims priority under 35 U.S.C. § 119 to Chinese Patent Application No. 202211611634.1, filed on Dec. 14, 2022, in the China National Intellectual Property Administration, the disclosure of which is incorporated by reference herein in its entirety.

### BACKGROUND

### 1. Field

Example embodiments of the present disclosure relate to a printed circuit board (PCB), and in particular, to a PCB preventing moisture penetration and warpage.

### 2. Description of Related Art

Printed circuit boards (PCBs) used in various electronic products have been continuously developed in response to a growing demand for smaller and faster electronic devices with higher functionality.

In particular, as sizes of various electronic products including PCBs become smaller, making PCBs smaller and thinner has become an important task, and a lot of research is being conducted at this stage. However, the thinner the thickness of the PCB, the less rigid it is and the easier it is to warp. Furthermore, in a process of manufacturing the PCB, when the PCB is detached from a stamping mold, a periphery of the PCB and a separation film easily lead to a pulling force on the PCB during demolding due to a large adhesive force, which causes poor warpage and seriously affects a workability of a plastic packaging process.

In addition, with a wide use of integrated circuit (IC) products, higher requirements are placed on the lifespan and reliability of IC products. However, the lifespan of IC products is largely affected by moisture. Particularly, at an interface where a substrate of the PCB is combined with the epoxy molding compound (EMC), moisture penetration is likely to occur, which may cause a degradation of electrical performances of IC products, thereby deteriorating the reliability of IC products and shortening their service life. The PCB is prone to warping due to due to its thinness, which also increases a possibility of moisture penetration.

### SUMMARY

Provided is a printed circuit board (PCB) which may improve warpage and prevent moisture penetration.

Additional aspects will be set forth in part in the description which follows and, in part, will be apparent from the description, or may be learned by practice of the presented embodiments.

According to an aspect of an example embodiment, there is provided a printed circuit board, divided into a printed circuit board area and a peripheral area surrounding the printed circuit board area, the printed circuit board including: a plurality of unit printed circuit boards provided in the printed circuit board area; a base portion provided in the peripheral area and the printed circuit board area, and including a circuit pattern portion and an insulating material portion; a first solder resist portion provided in the peripheral area on a first surface of the base portion and a second surface of the base portion, the first surface being opposite to the second surface; and a second solder resist portion provided in the printed circuit board area on the first surface of the base portion and the second surface of the base portion, wherein the first solder resist portion surrounds the second solder resist portion in the printed circuit board area, and wherein the first solder resist portion includes a first filler and the second solder resist portion includes a second filler that is different from the first filler.

According to an aspect of an example embodiment, there is provided a printed circuit board including: a printed circuit board area; a peripheral area surrounding the printed circuit board area; a base portion provided in the peripheral area and the printed circuit board area; a first solder resist portion provided in the peripheral area on a first surface of the base portion and a second surface opposite to the first surface of the base portion; and a second solder resist portion provided in the printed circuit board area on the first surface of the base portion and the second surface of the base portion, wherein the first solder resist portion surrounds the second solder resist portion in the printed circuit board area.

According to an aspect of an example embodiment, there is provided a printed circuit board including: a printed circuit board area; a peripheral area surrounding the printed circuit board area; a base portion provided in the peripheral area and the printed circuit board area; a first solder resist portion including: a first portion provided in the peripheral area on a first surface of the base portion, and a second portion provided in the peripheral area on a second surface opposite to the first surface of the base portion; and a second solder resist portion including: a first portion provided in the printed circuit board area on the first surface of the base portion, and a second portion provided in the printed circuit board area on the second surface of the base portion, wherein the first solder resist portion surrounds the second solder resist portion in the printed circuit board area.

### BRIEF DESCRIPTION OF THE DRAWINGS

The above and other aspects, features, and advantages of certain example embodiments of the present disclosure will be more apparent from the following description taken in conjunction with the accompanying drawings, in which:

FIG. 1A is a top view illustrating a printed circuit board (PCB) according to an example embodiment;

FIG. 1B is a bottom view illustrating a PCB according to an example embodiment;

FIG. 2 is a cross-sectional view illustrating a PCB according to an example embodiment;

FIG. 3 is a diagram of a structural formula, according to an example embodiment;

FIG. 4 is a top view illustrating a PCB according to an example embodiment; and

FIG. 5 is a cross-sectional view illustrating a PCB according to an example embodiment.

### DETAILED DESCRIPTION

Embodiments of the present disclosure will now be described more fully with reference to the attached drawings, in which example embodiments of the present disclosure are illustrated. This disclosure may, however, be implemented in many different forms, and should not be construed as limited to the embodiments set forth herein. Rather, these embodiments are provided so that the present disclosure will be thorough and complete, and will fully convey the conception of the embodiments of the present disclosure to those skilled in the art. In the following detailed description, a plurality of specific details are set forth by way of example to provide a full understanding of the relevant teachings. However, it should be apparent to those skilled in the art that the present teachings can be practiced without such details. In other instances, well-known methods, steps, and components are described at a relatively high level, without detail, to avoid unnecessarily obscuring aspects of the present teachings. The same reference numerals in the attached drawings refer to the same elements throughout, and thus descriptions thereof will not be repeated. In the attached drawings, sizes and relative sizes of layers, and regions may be exaggerated for clarity.

Further, in this specification, the phrase “on a plane,” or “plan view,” means viewing a target portion from the top, and the phrase “on a cross-section” means viewing a cross-section formed by vertically cutting a target portion from the side. Further, a “vertical direction” indicates an up-down direction in a cross-sectional view.

Hereinafter, the present disclosure will now be described fully with reference to the attached drawings.

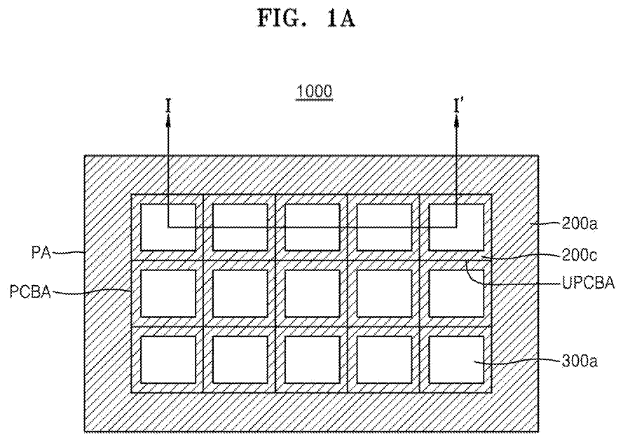

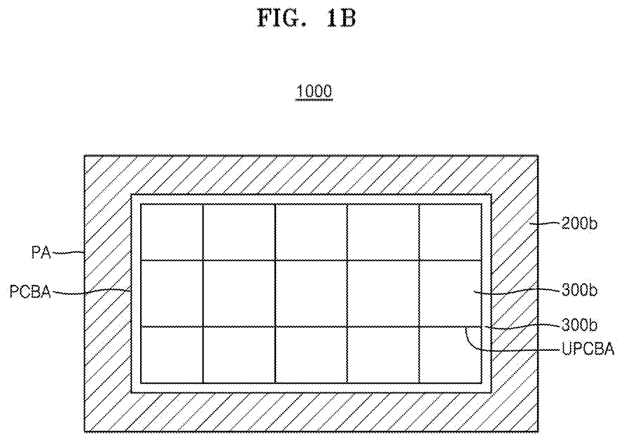

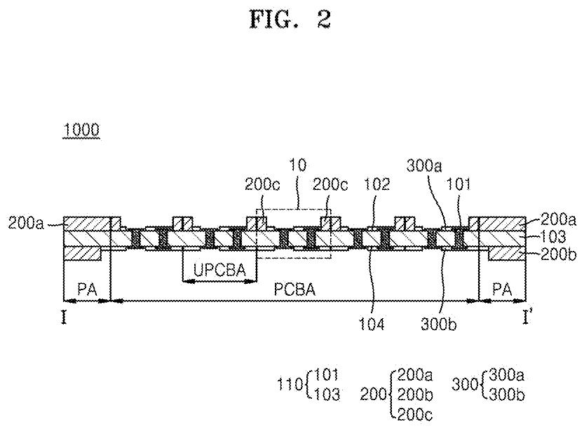

FIG. 1A is a top view illustrating a printed circuit board (PCB) according to an example embodiment. FIG. 1B is a bottom view illustrating a PCB according to an example embodiment. FIG. 2 is a cross-sectional view illustrating a PCB according to an example embodiment. FIG. 2 is the cross-sectional view taken along a line I-I′ in FIG. 1A, and a unit PCB 10 is marked with a dashed frame in FIG. 2 for convenience.

Referring to FIGS. 1A to 2, a PCB 1000 according to an example embodiment of the present disclosure may include a plurality of unit PCBs 10, and the PCB 1000 may be divided into a PCB area PCBA and a peripheral area PA surrounding the PCB area PCBA, where the plurality of unit PCBs 10 may be located in the PCB area PCBA. Chips or chip packages to be electrically connected to the PCB 1000 may be disposed in the PCB area PCBA. The peripheral area PA may be removed in a subsequent cutting process performed on the PCB 1000.

As illustrated in FIG. 2, the PCB 1000 may include a base portion 110, which may include a circuit pattern portion 101 and an insulating material portion 103 partially exposing the circuit pattern portion 101. The base portion 110 may be disposed in the peripheral area PA and the PCB area PCBA.

Each of the plurality of unit PCBs 10 may have the circuit pattern portion 101 and the insulating material portion 103 formed therein. In other words, each unit PCB 10 may have an electronic circuit formed therein and an insulating layer structure for the electronic circuit, such that a predetermined function may be performed. The circuit pattern portion 101 may be formed by an etching method of photolithography or by a process such as coating and the like, and may be connected to another circuit pattern portion 101 through a via hole, for example, passing through the insulating material portion 103. However, the circuit pattern portion 101 is not limited to a case illustrated in FIG. 2, but may be variously modified as desired.

The chips or chip packages to be electrically connected to the PCB 1000 may be disposed on each unit PCB 10, so as to implement the predetermined function of the chips.

A solder resist portion at least partially exposing the circuit pattern portion 101 may be disposed on a first surface 102 and a second surface 104 of the base portion 110, and the first surface 102 of the base portion 110 may be opposed to the second surface 104 of the base portion 110. The solder resist portion may include a first solder resist portion 200, and a second solder resist portion 300. In example embodiment, in order to simplify pattern structure and for convenience, the circuit pattern portions 101 exposed by the first and second resist portions 200 and 300 are not shown in the views of FIGS. 1A and 1B.

In an example embodiment, as illustrated in FIGS. 1A and 1B, the second solder resist portion 300 may include a solder resist portion 300a disposed on the first surface 102 and a solder resist portion 300b disposed on the second surface 104 of the base portion 110 in the PCB area PCBA. The first solder resist portion 200 may include a first solder resist portion 200a disposed on the first surface 102 of the base portion 110 in the peripheral area PA. As illustrated in FIG. 1A, the solder resist portion 200a of the first solder resist portion 200 disposed in the peripheral area PA may be disposed on the first surface 102 of the base portion 110 in a manner surrounding the PCB area PCBA. That is, the solder resist portion 200a of the first solder resist portion 200 disposed in the peripheral area PA may have a frame shape that surrounds the PCB area PCBA in the top view. In addition, the first solder resist portion 200 may further includes a solder resist portion 200b disposed on the second surface 104 of the base portion 110 in the peripheral area PA in the manner surrounding the PCB area PCBA, and a size of the solder resist portion 200b of the first solder resist portion 200 disposed on the second surface 104 of the base portion 110 may be smaller than that of the solder resist portion 200a of the first solder resist portion 200 disposed on the first surface 102 of the base portion 110 in the peripheral area PA, and the solder resist portion 300b of the second solder resist portion 300 may be disposed on the second surface 104 of the base portion 110 in the peripheral area PA. For example, as illustrated in FIG. 2, the solder resist portion 200b of the first solder resist portion 200 disposed on the second surface 104 of the base portion 110 in the peripheral area PA may be disposed side-by-side with the solder resist portion 300b of the second solder resist portion 300 on the second surface 104 in the peripheral area PA, and the solder resist portion 300b of the second solder resist portion 300 disposed on the second surface 104 of the base portion 110 in the peripheral area PA may be located between the solder resist portion 200b of the first solder resist portion 200 disposed on the second surface 104 and the PCB area PCBA.

The solder resist portion 300b of the second solder resist portion 300 disposed on the second surface 104 of the base portion 110 in the peripheral area PA may surround the PCB area PCBA on the second surface 104. In the peripheral area PA, the solder resist portion 200b of the first solder resist portion 200 formed on the second surface 104 may be combined with the solder resist portion 300b of the second solder resist portion 300 formed on the second surface 104. A combined portion between the solder resist portion 200b and the solder resist portion 300b may have various shapes, for example, a straight shape, serrated shape, wavy shape, pulsed shape, etc.

A thickness of the solder resist portion 200a of the first solder resist portion 200 disposed on the first surface 102 may be the same as a thickness of the solder resist portion 200b of the first solder resist portion 200 disposed on the second surface 104. However, the example embodiments of the disclosure are not limited thereto. In addition, referring to FIGS. 1A and 2, the PCB area PCBA may be divided into a plurality of unit PCB areas UPCBA according to the unit PCBs 10. Each unit PCB 10 may be disposed in a unit PCB area UPCBA. During the manufacturing process, the PCB 1000 may be cut according to the unit PCB area UPCBA after the PCB 1000 is manufactured, thereby each unit PCB 10 is obtained.

The second solder resist portion 300 (e.g., the solder resist portion 300a) may be disposed in each unit PCB area UPCBA. In each unit PCB area UPCBA, the second solder resist portion 300 may be disposed on the first surface 102 (e.g., solder resist portion 300a) and the second surface 104 (e.g., solder resist portion 300b) of the base portion 110. In addition, in each unit PCB area UPCBA, a solder resist portion 200c of the first solder resist portion 200 may also be formed on the first surface 102 of the base portion 110. The solder resist portion 200a of the first solder resist portion 200 disposed on the first surface 102 in the peripheral area PA may be disposed integrally with the solder resist portion 200c of the first solder resist portion 200 disposed on the first surface 102 in the corresponding unit PCB area UPCBA adjacent to the peripheral area PA. The solder resist portion 200a of the first solder resist portion 200 may surround the solder resist portion 300a of the second solder resist portion 300 on the first surface 102 in each unit PCB area UPCBA. That is, in an example embodiment of the present disclosure, the first solder resist portion 200 may be formed in a portion of each unit PCB area UPCBA and the peripheral area PA. For example, the solder resist portions 200a and 200b of the first solder resist portion 200 may be disposed on the first and second surfaces 102 and 104 of the base portion 110, respectively, in the peripheral area PA, and the solder resist portion 200c of the first solder resist portion 200 may be disposed on the first surface 102 of the base portion 110 in a portion of each unit PCB area UPCBA. In addition, the solder resist portion 200c of the first solder resist portion 200 formed in the unit PCB area UPCBA may be combined with the solder resist portion 300a of the second solder resist portion 300 on the first surface 102 of the base portion 110. A combined portion between the solder resist portion 200c and the solder resist portion 300a may have various shapes, for example, straight shape, serrated shape, wavy shape, pulsed shape, etc. Furthermore, the solder resist portion 200c of the first solder resist portion 200 is not formed on the second surface 104 of the base portion 110 in the unit PCB area UPCBA. Therefore, in a cross-sectional view (as shown in FIG. 2), the solder resist portion 200c of the first solder resist portion 200 on the first surface 102 of the base portion 110 may overlap with the solder resist portion 300b of the second solder resist portion 300 formed on the second surface 104 of the base portion 110 in a vertical direction in each unit PCB area UPCBA.

The solder resist portion 200c of the first solder resist portion 200 may be formed in the unit PCB area UPCBA, although the present disclosure is not limited thereto. That is, the first solder resist portion 200 may be formed only in the peripheral area PA of the PCB 1000 and not in the unit PCB area UPCBA. For example, the solder resist portion 200c of the first solder resist portion 200 may be not formed in the unit PCB area UPCBA. In this example, the first solder resist portion 200 may be formed only on the first surface 102 (e.g., solder resist portion 200a) and the second surface 104 (e.g., solder resist portion 200b) of the base portion 110 in the peripheral area PA. In this case, the first solder resist portion 200 (e.g., the solder resist portion 200a) formed in the peripheral area PA may be in direct contact with the second solder resist portion 300 (e.g., solder resist portion 300a) and combined with the second solder resist portion 300 to each other in a shape such as a straight shape, serrated shape, wavy shape, pulsed shape, etc.

In an example embodiment of the disclosure, the first solder resist portion 200 may be formed of the same material as the second solder resist portion 300, and a filler of the first solder resist portion 200 including the solder resist portions 200a to 200c may be different from a filler of the second solder resist portion 300 including the solder resist portions 300a and 300b. The filler of the first solder resist portion 200 may differ from the filler of the second solder resist portion 300 in that the filler of the first solder resist portion 200 may be modified to have hydrophobic groups, for example, a surface of the filler is wrapped with hydrophobic groups. When the filler includes silica or the like, the filler of the first solder resist portion 200 may include silica or the like with hydrophobic groups wrapped on its surface.

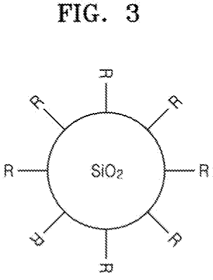

FIG. 3 is a diagram of a structural formula, according to an example embodiment. In the example structural formula of silica wrapped with hydrophobic groups shown in FIG. 3, R is a hydrophobic group.

In the related art, the fillers of the solder resist portions formed on the upper and lower surfaces of the base portion are the same. In this case, due to material properties forming the solder resist portion, moisture from the environment tends to penetrate into the peripheral area of the PCB, thereby causing deterioration of the reliability of the PCB and shortening its service life. However, according to embodiments of the present disclosure, the filler of the solder resist portion 200a and/or 200b of the first solder resist portion 200 formed in the peripheral area PA of the PCB 1000 may wrapped with hydrophobic groups on its surface, therefore the PCB 1000 according to the example embodiment may prevent the penetration of moisture, thereby a delamination issue of a package structure due to moisture may be prevented. Furthermore, according to the embodiments of the disclosure, the hydrophobic group is not particularly limited as long as it can improve moisture permeability.

In addition, in an example embodiment of the present disclosure, the solder resist portion 200c of the first solder resist portion 200 may be further formed on the first surface 102 of the base portion 110 in each unit PCB area UPCBA, and may surround the second solder resist portion 300 in each unit PCB area UPCBA, such that the first solder resist portion 200 may also protect each unit PCB 10 from moisture penetration into the unit PCB 10 after the unit PCB 10 is formed by the cutting.

On the other hand, in order to allow a rigidity of the first solder resist portion 200 greater than that of the second solder resist portion 300, a thickness of the first solder resist portion 200 formed on the base portion 110 may be thicker than that of the second solder resist portion 300 formed on the base portion 110. For example, a thickness of the first solder resist portion 200 may be about 35 μm and a thickness of the second solder resist portion 300 may be about 15 μm. Thus, the rigidity of the first solder resist portion 200 may be 1.3 times that of the rigidity of the second solder resist portion 300.

However, embodiments of the present disclosure are not limited thereto. When a ratio (e.g., weight ratio) of the filler of the first solder resist portion 200 to the first solder resist portion 200 increases, the rigidity of the first solder resist portion 200 may be also enhanced. Accordingly, the weight ratio of the filler of the first solder resist portion 200 to the first solder resist portion 200 may be higher than the weight ratio of the filler of the second solder resist portion 300 to the second solder resist portion 300 to increase the rigidity of the PCB 1000, such that the rigidity of the first solder resist portion 200 is greater than that of the second solder resist portion 300.

In the example embodiment, the thickness of the second solder resist portion 300 disposed on the first surface 102 (e.g., solder resist portion 300a) may be the same as the thickness of the second solder resist portion 300 disposed on the second surface 104 (e.g., solder resist portion 300b). Further, although it is shown in the cross-sectional view that the thickness of the first solder resist portion 200 is thicker than that of the second solder resist portion 300, it is not limited thereto. For example, the thickness of the first solder resist portion 200 may be the same as the thickness of the second solder resist portion 300.

As a result, the PCB 1000 according to the embodiment may improve the overall rigidity, thereby reducing an overall warpage of a substrate and a series of problems caused by the warpage. In addition, the first solder resist portion 200 formed in the peripheral area PA (e.g., solder resist portion 200a and/or 200b) has hydrophobicity, such that issues, including interface delamination, caused by moisture may be prevented.

In the foregoing embodiments, the warpage of the PCB 1000 is prevented by increasing the rigidity thereof, but embodiments of the disclosure are not limited thereto. As in the embodiments described below, the warpage caused by a large bonding force with a separation film of a mold is avoided by providing an easier separation of the first solder resist portion 200 from the separation film in a compression molding process.

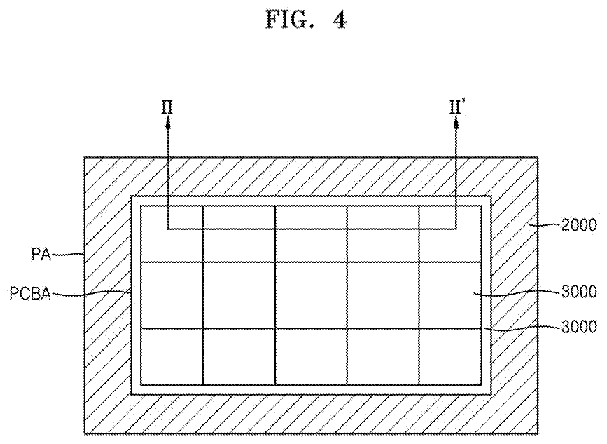

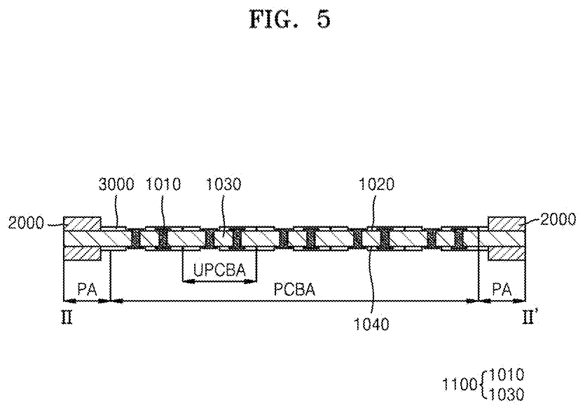

FIG. 4 is a top view illustrating a PCB according to an example embodiment. FIG. 5 is a cross-sectional view illustrating a PCB according to an example embodiment. FIG. 5 illustrates the cross-sectional view taken along a line II-II′ in FIG. 4.

In order to avoid redundant explanation, the descriptions of the PCBs of FIGS. 4 and 5 will focus on differences from the PCBs of the previous embodiments. Components not individually explained in the following description of this embodiment are consistent with those of the preceding embodiments. The same reference numbers will be used to refer to the same components, and similar reference numbers will be used to refer to similar components.

Referring to FIGS. 4 and 5, the first solder resist portion 2000 may be only formed in the peripheral area PA of the PCB. That is, in this embodiment, the first solder resist portion 2000 may be formed on the first surface 1020 and the second surface 1040 of the base portion 1100 in the peripheral area PA without being formed in the PCB area PCBA surrounded by the peripheral area PA. In addition, the second solder resist portion 3000 may be formed on the first surface 1020 of the base portion 1100 in the peripheral area PA. The first solder resist portion 2000 may surround the second solder resist portion 3000 on each of the first surface 1020 and the second surface 1040 in the peripheral area PA. Furthermore, the first solder resist portion 2000 formed in the peripheral area PA may be in direct contact with the second solder resist portion 3000 in the peripheral area PA. The first solder resist portion 2000 are combined with the second solder resist portion 3000. A combined portion between the first solder resist portion 2000 and the second solder resist portion 3000 may have a shape such as a straight shape, a serrated shape, a wavy shape, a pulsed shape, etc. On each of the first surface 1020 and the second surface 1040, the second solder resist portion 3000 formed in the peripheral area PA may be formed integrally with a solder resist portion formed in the unit PCB area UPCBA adjacent to the peripheral area PA.

In an encapsulated compression molding process on the PCB, the first solder resist portion 2000 may be contact with the separation film on the mold directly. To easily separate from the mold, the filler of the first solder resist portion 2000 may be wrapped with a wax-based material to reduce the bonding force between the first solder resist portion 2000 and the separation film. In an example embodiment, a surface of the filler of the first solder resist portion 2000 may be wrapped with a wax-based material. In this way, the first solder resist portion 2000 may be easily separated from the separation film on the mold so as to separate from the mold. Therefore, according to the example embodiment, a pulling force on the PCB during separation from the mold is reduced, thereby reducing the possibility of warpage.

Also, in an example embodiment, the thickness of the first solder resist portion 2000 may be the same as the thickness of the second solder resist portion 3000, but the present disclosure is not limited thereto. The thickness of the first solder resist portion 2000 may be greater than that of the second solder resist portion 3000 to further improve the rigidity of the PCB. That is, the thickness of the first solder resist portion 2000 may be greater than or equal to the thickness of the second solder resist portion 3000.

In addition, since the filler of the first solder resist portion 2000 may be wrapped with a wax-based material on the surface thereof, the first solder resist portion 2000 may further be used to prevent the moisture penetration.

Although the embodiments described in FIGS. 1A to 3 and FIGS. 4 and 5 are described separately, aspects of each embodiment may be combined without departing from the scope of the disclosure.

The PCB according to example embodiments of the disclosure may improve blockage in an encapsulation process and poor soldering due to large warpage, and may improve interface delamination issue due to moisture absorption simultaneously. Further, the bonding force between the printed circuit board and a separation film in separating the PCB from a mold may be reduced during an encapsulated compression molding process.

The PCB according to the example embodiments of the present disclosure may prevent moisture penetration and/or be easily demolded by changing the solder resist materials formed on the surface of the base portion to solder resist materials including two different fillers and changing an arrangement of the solder resist materials.

Further, in the PCB according to the example embodiments of the present disclosure, the thickness of the first solder resist material formed in the peripheral area may be greater than the thickness of the second solder resist material formed in the PCB area surrounded by the peripheral area, such that the rigidity of the PCB may be improved.

In addition, in the PCB according to the example embodiment of the present disclosure, compared with the second solder resist material, the rigidity of the PCB may be increased by increasing a content of the filler of the first solder resist material in the first solder resist material.

While various embodiments have been illustrated and described above, it will be understood by those skilled in the art that various modifications, additions and substitutions are possible, without departing from the scope of the present disclosure. Therefore, the embodiments disclosed in this specification are only for illustrative purposes rather than limiting the technical scope of the present disclosure. The scope of the present disclosure must be limited by the appended claims.

What is claimed is:

1. A printed circuit board, divided into a printed circuit board area and a peripheral area surrounding the printed circuit board area, the printed circuit board comprising:
a plurality of unit printed circuit boards provided in the printed circuit board area;
a base portion provided in the peripheral area and the printed circuit board area, and comprising a circuit pattern portion and an insulating material portion;
a first solder resist portion provided in the peripheral area on a first surface of the base portion and a second surface of the base portion, the first surface being opposite to the second surface; and
a second solder resist portion provided in the printed circuit board area on the first surface of the base portion and the second surface of the base portion,
wherein the first solder resist portion surrounds the second solder resist portion in the printed circuit board area, and
wherein the first solder resist portion comprises a first filler of and the second solder resist portion comprises a second filler that is different from the first filler.

2. The printed circuit board of claim 1, wherein the printed circuit board area comprises a plurality of unit printed circuit board areas,
wherein each of the plurality of unit printed circuit boards is in at least one unit printed circuit board area of the plurality of unit printed circuit board areas, and
wherein the second solder resist portion is provided on the first surface of the base portion and the second surface of the base portion in each of the plurality of unit printed circuit board areas.

3. The printed circuit board of claim 2, wherein the first filler of the first solder resist portion is wrapped with hydrophobic groups.

4. The printed circuit board of claim 3, wherein the first solder resist portion is provided at a periphery of the second solder resist portion on the first surface of the base portion and contacts the second solder resist portion, in each of the plurality of unit printed circuit board areas.

5. The printed circuit board of claim 4, wherein the second solder resist portion is further provided in the peripheral area on the second surface of the base portion, and
wherein the second solder resist portion in the peripheral area on the second surface is between the first solder resist portion on the second surface in the peripheral area and the printed circuit board area.

6. The printed circuit board of claim 3, wherein a weight ratio of the first filler of the first solder resist portion to the first solder resist portion is greater than a weight ratio of the second filler of the second solder resist portion to the second solder resist portion, and
wherein a thickness of the first solder resist portion is greater than or equal to a thickness of the second solder resist portion.

7. The printed circuit board of claim 2, wherein the first filler of the first solder resist portion is wrapped with wax-based material.

8. The printed circuit board of claim 7, wherein the second solder resist portion is further provided in the peripheral area on the first surface of the base portion and the second surface of the base portion, and
wherein the second solder resist portion in the peripheral area is between the first solder resist portion in the peripheral area and the printed circuit board area on each of the first surface of the base portion and the second surface of the base portion.

9. The printed circuit board of claim 7, wherein a thickness of the first solder resist portion is greater than or equal to a thickness of the second solder resist portion.

10. The printed circuit board of claim 8, wherein a combined portion between the first solder resist portion and the second solder resist portion has a straight shape, a serrated shape, a wavy shape or a pulsed shape in the peripheral area.

11. A printed circuit board comprising:
a printed circuit board area;
a peripheral area surrounding the printed circuit board area;
a base portion provided in the peripheral area and the printed circuit board area;
a first solder resist portion provided in the peripheral area on a first surface of the base portion and a second surface opposite to the first surface of the base portion; and
a second solder resist portion provided in the printed circuit board area on the first surface of the base portion and the second surface of the base portion,
wherein the first solder resist portion surrounds the second solder resist portion in the printed circuit board area.

12. The printed circuit board of claim 11, wherein the first solder resist portion comprises a first filler and the second solder resist portion comprises a second filler that this different from the first filler.

13. The printed circuit board of claim 12, wherein a weight ratio of the first filler of the first solder resist portion to the first solder resist portion is greater than a weight ratio of the second filler of the second solder resist portion to the second solder resist portion.

14. The printed circuit board of claim 13, wherein a thickness of the first solder resist portion is greater than or equal to a thickness of the second solder resist portion.

15. The printed circuit board of claim 12, wherein the first filler of the first solder resist portion is wrapped with hydrophobic groups.

16. The printed circuit board of claim 12, wherein the first filler of the first solder resist portion is wrapped with wax-based material.

17. The printed circuit board of claim 11, wherein the first solder resist portion is provided at a periphery of the second solder resist portion on the first surface of the base portion and contacts the second solder resist portion.

18. The printed circuit board of claim 17, wherein the second solder resist portion is further provided in the peripheral area on the second surface of the base portion, and
wherein the second solder resist portion in the peripheral area on the second surface is between the first solder resist portion on the second surface in the peripheral area and the printed circuit board area.

19. The printed circuit board of claim 18, wherein the second solder resist portion is further provided in the peripheral area on the first surface of the base portion and the second surface of the base portion, and
wherein the second solder resist portion in the peripheral area is between the first solder resist portion in the peripheral area and the printed circuit board area on each of the first surface of the base portion and the second surface of the base portion.

20. A printed circuit board comprising:
a printed circuit board area;
a peripheral area surrounding the printed circuit board area;
a base portion provided in the peripheral area and the printed circuit board area;
a first solder resist portion comprising:
a first portion provided in the peripheral area on a first surface of the base portion, and
a second portion provided in the peripheral area on a second surface opposite to the first surface of the base portion; and
a second solder resist portion comprising:
a first portion provided in the printed circuit board area on the first surface of the base portion, and
a second portion provided in the printed circuit board area on the second surface of the base portion,
wherein the first solder resist portion surrounds the second solder resist portion in the printed circuit board area.
